(19) United States
(12) Patent Application Publication
(10) Pub. No.: US 2017/0125135 A1
(43) Pub. Date: May 4, 2017

(54) NOBLE METAL-COATED COPPER WIRE FOR BALL BONDING

(71) Applicant: TANAKA DENSHI KOGYO K.K., Saga-ken (JP)

(72) Inventors: Hiroyuki AMANO, Saga-ken (JP); Somei YARITA, Saga-ken (JP); Yusuke SAKITA, Saga-ken (JP); Yuki ANTOKU, Saga-ken (JP); Wei CHEN, Saga-ken (JP)

(21) Appl. No.: 15/337,771

(22) Filed: Oct. 28, 2016

(30) Foreign Application Priority Data
Nov. 2, 2015 (JP) 2015-215919

(51) Int. Cl. H01B 1/02; H01L 23/00

(52) U.S. Cl. CPC H01B 1/026; H01L 24/11; H01L 24/16; H01L 2224/1134; H01L 2924/01029; H01L 2924/01046; H01L 2224/16503

(57) ABSTRACT

A noble metal-coated copper wire for ball bonding, with a wire diameter between 10 μm or more, and 25 μm or less, includes a core material having a copper alloy having a copper purity of 98 mass % or higher, and a noble metal-coating layer formed on the core material. The noble metal-coating layer includes a palladium cavitating layer containing palladium; at least one element selected from the group consisting of Group 13 to 16 elements or an oxygen element, finely dispersed in the palladium; and a diffusion layer formed of copper diffused into the palladium. The noble metal-coating layer may include a palladium cavitating layer containing palladium, at least one element selected from the group consisting of Group 13 to 16 elements or an oxygen element, finely dispersed therein, and a nickel intermediate layer disposed between the core material and the noble metal-coating layer.

### TECHNICAL FIELD

The present invention relates to a noble metal-coated copper wire for ball bonding having a wire diameter of 10 μm or more and 25 μm or less, and suitable for connection between IC chip electrodes and substrates, such as external leads, used in semiconductor devices. In particular, the present invention relates to a noble metal-coated copper wire for ball bonding in which a high-concentration palladium (Pd) concentrated layer is stably formed on the surface of a solidified ball.

### BACKGROUND ART

In general, a method called “ball bonding” is used in first bonding between coated copper bonding wires and electrodes, and a method called “wedge bonding” is used in second bonding between coated copper bonding wires and wiring on circuit wiring boards for semiconductors. In the first bonding, arc heat input is applied to the tip of the coated copper bonding wire by electronic flame-off (EFO) discharge current. In the EFO process, the angle between the tip of the bonding wire and the tip of the discharge torch is generally 60 degrees or less from the longitudinal direction of the wire. According to the EFO process, spark discharge is ignited between the discharge torch and the wire tip to form a molten ball portion at the tip of the bonding wire for about several hundreds of microseconds, and the ball portion is connected to an aluminum pad on the electrode.

When the process from the formation of a molten ball to the solidification thereof is observed, the tip of the bonding wire first starts to melt, and a small molten ball is formed. The molten ball autonomously becomes spherical due to the surface tension. Thereafter, the small molten ball grows to form a true sphere called a “free air ball (FAB)” at the tip of the wire, like a Japanese sparkler. After the FAB is melted and solidified, it is ball-bonded to the aluminum pad. At this point, ultrasonic waves are applied while heating the electrode on the aluminum pad at a temperature within a range of 150 to 300° C. to press-bond the FAB, thereby bonding the bonding wire in a hemispherical shape to the aluminum pad on the chip.

The term “FAB” used herein refers to a molten ball formed at the tip of a coated copper bonding wire extending from the tip of a bonding tool by spark discharge of the tip of the bonding wire while spraying non-oxidative gas or reducing gas, such as nitrogen or nitrogen-hydrogen, to the tip of the bonding wire.

Moreover, examples of the material of the aluminum pad include 99.99 mass % or higher pure aluminum (Al), an aluminum (Al)-1 mass % silicon (Si) alloy, an aluminum (Al)-0.5 mass % copper (Cu) alloy, an aluminum (Al)-1 mass % silicon (Si)-0.5 mass % copper (Cu) alloy, and the like.

Conventionally, palladium (Pd)-coated copper wires have been used as bonding wires for connecting IC chip electrodes and external leads in semiconductor devices. For example, Japanese Unexamined Utility Model Application Publication No. 60-160554 proposes “a bonding fine wire for semiconductors, wherein a coating layer of Pd or a Pd alloy is provided around the outer periphery of a core wire of Cu or a Cu alloy directly or via an intermediate layer.” Thereafter, a practical palladium (Pd)-coated copper wire was developed in Japanese Unexamined Patent Application Publication No. 2004-014884 (PTL 1, described later) as “a bonding wire having a core material and a coating layer formed on the core material, wherein the core material comprises a material, other than gold, having a micro Vickers hardness of 80 Hv or less, and the coating layer comprises a metal having a melting point higher by 300° C. or more than that of the core material and having higher oxidation resistance than copper.”

Further, an article under the title of “Development of Hybrid Bonding Wire” by Shingo Kaimori et. al. (SEI Technical Review, July 2006, No. 169, starting from page 47; NPL 1, described later) introduces “a plating coating wire having a diameter of 25 μm coated with 0.1 μm of oxidation-resistant metal.” There is also a patent application in which the interface between the core material and the coating layer is analyzed (Japanese Unexamined Patent Application Publication No. 2010-272884).

In these palladium (Pd)-coated copper wires, palladium (Pd) is distributed on the surface of the bonding wire, as shown in photograph 5 on page 50 of NPL 1, and the wire loop is thus stable. Moreover, in the palladium (Pd)-coated copper wires, palladium (Pd) from a palladium (Pd) stretched layer is distributed on the surface of the molten ball. Due to the presence of palladium (Pd) on the surface, when an intermetallic compound of aluminum (Al) and copper (Cu) is produced in the interface between the molten ball and the aluminum pad, the growth rate of this intermetallic compound is supposed to be slower than in the cases of gold bonding wires.

Accordingly, there has been a demand for palladium (Pd)-coated copper wires in which palladium (Pd) is uniformly dispersed in the bonding interface between the molten ball and the aluminum pad. However, the following problems have existed: when the thickness of the palladium (Pd) stretched layer in the palladium (Pd)-coated copper wire is increased, the molten ball is unstable, whereas when the thickness of the palladium (Pd) stretched layer is reduced, most of palladium (Pd) is buried in the molten ball and alloyed with the core material component, and palladium (Pd) is not present in the bonding interface with the aluminum pad. Moreover, when the wire diameter of a bonding wire is reduced from 25 μm to 20 μm or less, the so-called erratic ball problem occurs, wherein a molten ball is less likely to be formed on the central axis line of the wire.

That is, it has been known so far that, when palladium (Pd) is present on the surface of the molten ball, the formation of AlCu intermetallic compounds in the interface with the aluminum pad is prevented. In those cases, however, stable formation of a palladium (Pd) concentrated layer on the entire surface of the molten ball was not realized, as shown in FIG. 10A of Re-publication of PCT International Publication No. 2013-111642.

Moreover, Japanese Unexamined Patent Application Publication No. 2013-42105 (PTL 2, described later) proposes an invention relating to “a bonding wire comprising a core material of copper and inevitable impurities, and a Pd coating layer formed on the core material, the Pd coating layer having a cross-sectional area of 0.1 to 1.0% based on the total cross-sectional area of the wire (Claim 1 of PTL 2). FIG. 2a (c) of PTL 2, which shows a photograph of the surface of a molten ball, indicates that “Pd (white dots) is spread over the entire FAB (ball b).”

However, when noble metal-coated copper wires for ball bonding are mass-produced, the surface shape of the core wire or the coated core wire always changes due to the abrasion of diamond dies. Moreover, the shape of the cut surface of the tip of the coated copper wire when the wire is torn off during the second bonding always changes as well. Accordingly, when a FAB is formed, it is extremely difficult to retain, on the surface of the molten ball, palladium (Pd) within a thin palladium (Pd) stretched layer. If the thickness of the palladium (Pd) stretched layer is increased, the molten ball tends to vary. Therefore, it is extremely difficult to put in practical use the invention disclosed in Japanese Unexamined Patent Application Publication No. 2013-42105 (PTL 2, described later).

On the other hand, for the purpose of providing a palladium (Pd)-coated copper wire for ball bonding suitable for mass production, wherein palladium (Pd) can be uniformly dispersed on the surface of the molten ball, Japanese Patent Application No. 2015-172778 filed by the present applicant disclosed an invention relating to “a palladium (Pd)-coated copper wire for ball bonding, the wire having a wire diameter of 10 to 25 μm, and comprising a core material comprising pure copper (Cu) or a copper alloy having a copper (Cu) purity of 98 mass % or higher, and a palladium (Pd) stretched layer formed on the core material; wherein the palladium (Pd) stretched layer is a palladium (Pd) layer containing sulfur (S), phosphorus (P), boron (B), or carbon (C).”

According to this invention, the surface of the molten and solidified ball could be almost uniformly coated with palladium (Pd), as shown in the photograph of the surface of the molten ball in FIG. 2a (c) of Japanese Unexamined Patent Application Publication No. 2013-42105 (PTL 2, described later).

However, when such a solidified ball coated with palladium (Pd) is cut in half and the cross-section thereof was observed, it has been found that the palladium (Pd) layer flowed into the inside of the solidified ball, as shown in FIG. 5 which shows a photograph of the cross-sectional distribution of palladium (Pd) taken by an Auger electron spectrometer, and that voids were formed along the flow of palladium (Pd) in the inside of the solidified ball, as shown in FIG. 6 which shows a photograph of the cross-section of a bonding wire taken by a scanning electron microscope. It also has been found that such voids changed depending on the amount of palladium (Pd) entrained.

When a thick palladium (Pd) stretched layer has been provided on a copper core material, unlike the invention disclosed in Japanese Patent Application No. 2015-172778, it has been found that there were cases in which the palladium (Pd) stretched layer was completely entrained into the inside of the molten ball during the formation process of the molten ball, as shown in FIG. 7 which shows a photograph of the cross-sectional distribution of palladium (Pd) in a bonding wire taken by an Auger electron spectrometer. In this case, no palladium (Pd) concentrated layer is present on the surface of the molten and solidified copper ball. On the contrary, when a thin palladium (Pd) stretched layer is provided on a copper core material, it will be alloyed with the molten ball in the process of formation of the molten ball, as stated above. In this case as well, no palladium (Pd) concentrated layer is present on the surface of the molten and solidified copper ball.

Under these circumstances, there has been a demand for a structure of a bonding wire that allows stable dispersion of palladium (Pd) on the entire surface of the molten copper ball, and is suitable for mass production.

### CITATION LIST

### Non-Patent Literature

[NPL 1] Shingo Kaimori et. al., “Development of Hybrid Bonding Wire, ” SEI Technical Review, July 2006, No. 169, starting from page 47

### Patent Literature

PTL 1: Japanese Unexamined Patent Application Publication No. 2004-014884
PTL 2: Japanese Unexamined Patent Application Publication No. 2013-42105

The present inventors re-examined in detail the process of formation of molten copper balls in conventional noble metal-coated copper wires. The process of formation of molten copper balls is a phenomenon occurring in a short period of time, such as about several hundreds of microseconds. In outline, the process of formation of molten balls in noble metal-coated bonding wires, which have a thin noble metal coating, is mostly the same as the process of formation of molten balls in pure copper wires. When spark current by discharge flows in the tip of a pure copper wire, the tip of the core material first generates heat, and a small molten ball is formed. The small molten ball climbs up the wire, and grows to a large molten ball to form a FAB.

Considering the molten ball, regardless of the size of the molten ball, it becomes a sphere due to the surface tension. The bottom of the molten ball distant from the wire is a high-temperature side, and the upper portion is a low-temperature side. Because of this temperature difference, a large convection flowing from the top to the bottom along the center line of the wire is formed, and the large convection flows on the surface of the molten ball. However, conventional noble metal-coated copper wires have been developed without understanding the process of formation of molten copper balls. Accordingly, the palladium (Pd) concentrated layer cannot be stably and uniformly dispersed on the entire surface of the molten ball. In fact, the distribution of the conventional palladium (Pd) concentrated layer has been limited to part of the surface of the molten copper ball (see FIG. 2a (c) of PTL 2).

In addition, the present inventors also re-examined the coating process of palladium (Pd) in conventional noble metal-coated copper wires. In conventional noble metal-coated copper wires, conventional wet palladium (Pd) plating layers have been used as substitutes to form noble metal-coating layers on the copper wires. This is because a well-known wet palladium (Pd) plating bath used for printed circuit boards and electrical parts, such as connectors and electrical contacts, have been used as substitutes for palladium (Pd) plating of noble metal-coated copper wires.

However, these electrical parts use a palladium (Pd) plating layer itself as the product surface. Accordingly, in order to maintain the product quality of palladium (Pd) plating, it was necessary to prevent embrittlement by hydrogen within the plating layer. Specifically, since palladium (Pd) metal is a hydrogen-absorbing metal, palladium (Pd) has a characteristic of absorbing a large amount of hydrogen. Moreover, in wet plating of palladium (Pd), palladium (Pd) is deposited together with hydrogen. Therefore, the palladium (Pd) deposited under such conditions has characteristics of absorbing hydrogen and having a large electrodeposition stress (“Kinzoku Hyomen Gijutsu Binran” (Handbook of Metal Surface Finishing Technology) edited by The Surface Finishing Society of Japan, (1976) page 367). The wet plating bath also includes plating bathes using an alcohol-containing aqueous solution, such as ethanol.

In order to eliminate the hydrogen absorbed in the palladium (Pd) coating, baking treatment is generally performed in a baking oven as the post-treatment of palladium (Pd) wet plating (“Guidebook for Plating Technique,” edited by Tokyo Plating Material Cooperative Association, (1967) page 619). Similarly, when nickel plating is performed, heat treatment is generally performed to eliminate hydrogen embrittlement after plating (see Annex 6 of JIS H8617). The study results of the present inventors revealed that, in conventional noble metal-coated copper wires, such a conventional wet palladium (Pd) plating layer have been used as substitutes to form a noble metal-coating layer on the copper wires.

However, in noble metal-coated copper wires for use in ball bonding, the deposited palladium (Pd) coating forms a palladium (Pd) concentrated layer of the molten ball. Thus, the wet plating layer itself is not used as the bonding surface, as is the case with other products. In the first bonding, a molten ball is formed, and in the second bonding, the clean copper (Cu) surface is bonded by wedge bonding. It is important here that fine particles of palladium (Pd) are dispersed on the surface of the molten copper ball, and that a palladium (Pd) concentrated layer is formed on the surface of the solidified ball. Therefore, the copper wire after noble metal coating does not require baking treatment or intermediate heat treatment after primary wire drawing and before secondary wire drawing, in order to increase the product quality. In the present invention, the term “palladium (Pd) cavitating layer” was used in order to clarify that the palladium (Pd)-coating layer is easily divided from the core material during the formation of a molten ball.

Even if hydrogen molecules and atoms are present in the palladium (Pd) cavitating layer or the palladium (Pd) cavitated layer, these hydrogen molecules and the like cannot remain in the palladium (Pd) concentrated layer when the palladium (Pd) cavitating layer is melted. The palladium (Pd) cavitated layer in which Group 13 to 16 contained elements are discharged and released from the palladium (Pd) cavitating layer is likely to be divided by a large convection, regardless of the presence of hydrogen molecules and the like. Furthermore, even if hydrogen molecules and the like are dissolved in the palladium (Pd) cavitating layer, when the amount of palladium (Pd) which enters the inside of the molten copper due to the division is low, defects on the bonding surface caused by large voids can be avoided.

The present inventors examined the above-mentioned process of formation of molten balls, and consequently succeeded in uniformly forming a palladium (Pd) concentrated layer on the surface of a molten copper ball by using as a palladium (Pd) coating layer a palladium (Pd) cavitating layer in which one or two or more contained elements selected from Group 13 to 16 elements and oxygen elements, which easily flow out, are finely dispersed. That is, in the production process of a bonding wire, contained elements, such as Group 13 to 16 elements having a low melting point, may be transferred to the interface of the core material. Moreover, since the palladium (Pd) cavitating layer is thin, when the contained elements are transferred to the interface of the core material during the formation of the molten copper ball, the palladium (Pd) cavitating layer becomes a palladium (Pd) cavitated layer.

On the other hand, during the growth process of the molten copper ball, the palladium (Pd) cavitated layer is divided in the shape of wedges by the flow of the large convection on the surface of the molten ball. The palladium (Pd) cavitated layer divided on the surface of the molten ball is dispersed in the form of fine particles. The dispersed palladium (Pd) is not in the form of metal ions, but binds to the molten copper (Cu). The present inventors succeeded in stably forming a palladium (Pd) concentrated layer on the entire surface of the molten copper ball by the quantum-mechanical bond in the core material interface.

According to the present invention, the process of formation of a molten ball can be considered as follows. When spark current reaches the noble metal-coated copper wire, a small molten ball is initially formed from the copper core material. Since the order of melting depends on the melting point, Group 13 to 16 surface-active elements are melted first. When a gold (Au) layer is present, gold (Au) is melted, then the copper (Cu) of the core material is melted, and finally palladium (Pd) is melted. The palladium (Pd) cavitated layer from which the Group 13 to 16 surface-active elements are released is fragile and is easily formed into fine particles.

As a result, when the solid palladium (Pd) cavitated layer having a high melting point receives the surface tension of the molten ball, the palladium (Pd) cavitated layer is divided and melted. The palladium (Pd) cavitated layer melted in the surface side is cooled by the air, immediately forms a thin layer and is fixed. On the other hand, the palladium (Pd) cavitated layer melted in the copper ball side is entrained into the inside of the copper ball. Even if a thin layer is formed, copper (Cu) has a melting point lower than that of palladium (Pd) by 500° C. or more; therefore, the molten copper (Cu) still forms a large convection in the inside of the thin layer. Therefore, a less amount of the palladium (Pd) cavitated layer is melted in the inside, and it is uniformly mixed and alloyed due to the large convection.

When the small molten ball grows to several tens of μm, the part of the palladium (Pd) cavitated layer divided from the noble metal-coated copper wire is formed into wedges, and the palladium (Pd) cavitated layer successively follows. The above phenomenon is repeated. Therefore, even if there is a large convection on the surface of the molten ball, the palladium (Pd) cavitated layer melted on the surface is not entrained into the solidified ball, and the palladium (Pd) concentrated layer can be stably and uniformly distributed on the surface of the molten copper ball of the core material. Thus, it is possible to provide a noble metal-coated copper wire for ball bonding suitable for mass production.

An object of the present invention is to provide a noble metal-coated copper wire for ball bonding suitable for mass production, wherein a palladium (Pd) concentrated layer can be stably and uniformly dispersed on the entire surface of the molten copper ball of the core material. Another object of the present invention is to provide a noble metal-coated copper wire for ball bonding, wherein palladium (Pd) does not flow into the inside of the solidified copper ball, and no voids are formed.

### Solution to Problem

One of the noble metal-coated copper wires for ball bonding for solving the problem of the present invention is a noble metal-coated copper wire for ball bonding, the wire having a wire diameter of 10 μm or more and 25 μm or less, and comprising a core material comprising a copper alloy having a copper (Cu) purity of 98 mass % or higher, and a noble metal-coating layer formed on the core material;

wherein the noble metal-coating layer comprises:

a palladium (Pd) cavitating layer in which at least one or two or more contained elements selected from Group 13 to 16 elements and oxygen elements are finely dispersed; and a diffusion layer of palladium (Pd) and copper (Cu).

Another one of the noble metal-coated copper wires for ball bonding for solving the problem of the present invention is a noble metal-coated copper wire for ball bonding, the wire having a wire diameter of 10 μm or more and 25 μm or less, and comprising a core material comprising a copper alloy having a copper (Cu) purity of 98 mass % or higher, and a noble metal-coating layer formed on the core material;

wherein the noble metal-coating layer comprises:

a gold (Au) ultra-thin stretched layer;

a palladium (Pd) cavitating layer in which at least one or two or more contained elements selected from Group 13 to 16 elements and oxygen elements are finely dispersed; and

a diffusion layer of palladium (Pd) and copper (Cu).

Another one of the noble metal-coated copper wires for ball bonding for solving the problem of the present invention is a noble metal-coated copper wire for ball bonding, the wire having a wire diameter of 10 μm or more and 25 μm or less, and comprising a core material comprising a copper alloy having a copper (Cu) purity of 98 mass % or higher, and a noble metal-coating layer formed on the core material;

wherein the noble metal-coating layer comprises a palladium (Pd) cavitating layer in which at least one or two or more contained elements selected from Group 13 to 16 elements and oxygen elements are finely dispersed; and

wherein a nickel (Ni) intermediate layer is present between the core material and the noble metal-coating layer.

Another one of the noble metal-coated copper wires for ball bonding for solving the problem of the present invention is a noble metal-coated copper wire for ball bonding, the wire having a wire diameter of 10 μm or more and 25 μm or less, and comprising a core material comprising a copper alloy having a copper (Cu) purity of 98 mass % or higher, and a noble metal-coating layer formed on the core material;

wherein the noble metal-coating layer comprises a gold (Au) ultra-thin stretched layer, and a palladium (Pd) cavitating layer in which at least one or two or more contained elements selected from Group 13 to 16 elements and oxygen elements are finely dispersed; and

wherein a nickel (Ni) intermediate layer is present between the core material and the noble metal-coating layer.

### BRIEF DESCRIPTION OF DRAWINGS

FIG. 1 shows a copper (Cu) diffusion layer on the surface of the bonding wire of the present invention.

FIG. 2 shows the element distribution in the outermost surface of the bonding wire of the present invention analyzed using an Auger electron spectrometer.

FIG. 3 is a photograph of the cross-sectional distribution of palladium (Pd) in the bonding wire of the present invention taken by an Auger electron spectrometer.

FIG. 4 is a photograph of the cross-section of the bonding wire of the present invention taken by a scanning electron microscope.

FIG. 5 is a photograph of the cross-sectional distribution of palladium (Pd) in the bonding wire of the Comparative Example taken by an Auger electron spectrometer.

FIG. 6 is a photograph of the cross-section of the bonding wire of the Comparative Example taken by a scanning electron microscope.

FIG. 7 is a photograph of the cross-sectional distribution of palladium (Pd) in the bonding wire of the Comparative Example taken by an Auger electron spectrometer.

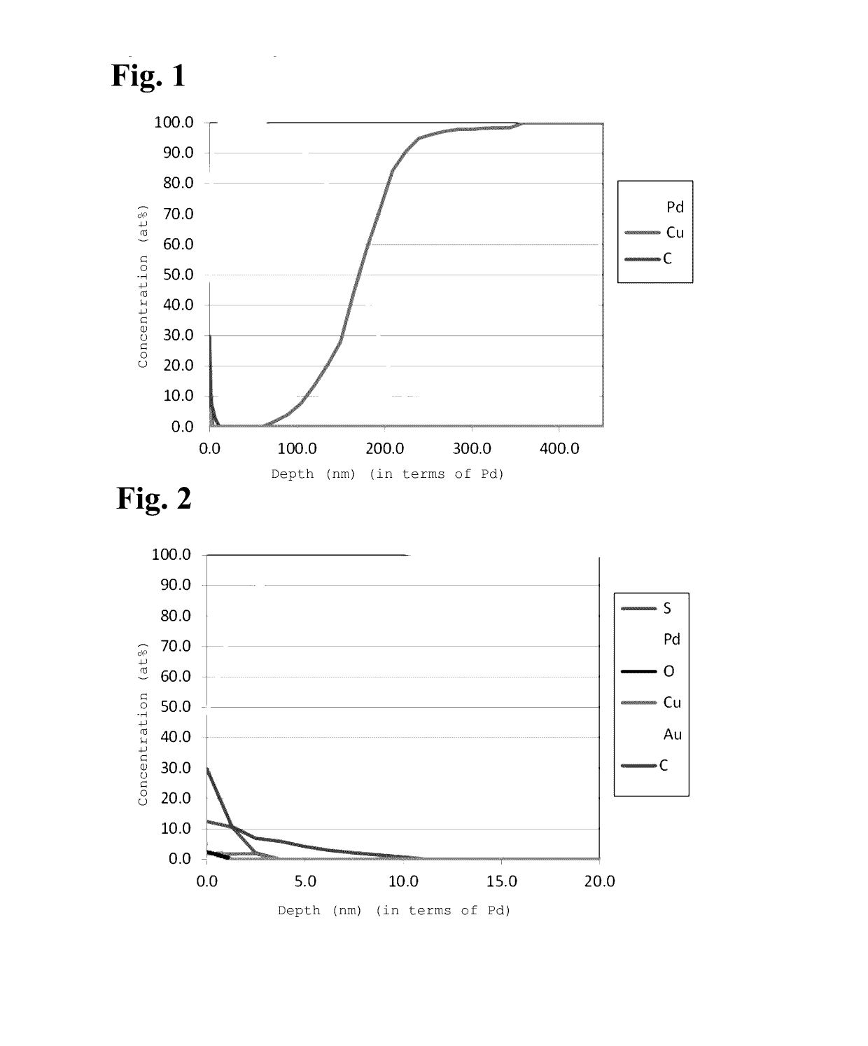

Preferred embodiments of the present invention are as follows. It is preferable that the at least one or two or more contained elements comprise one or two or more elements selected from sulfur (S), carbon (C), phosphorus (P), boron (B), silicon (Si), germanium (Ge), arsenic (As), selenium (Se), indium (In), tin (Sn), antimony (Sb), tellurium (Te), bismuth (Bi), and oxides thereof. Further, it is more preferable that the at least one or two or more contained elements comprise one or two or more contained elements selected from sulfur (S), phosphorus (P), selenium (Se), tellurium (Te), and oxygen elements. In particular, it is most preferable that the at least one or two or more contained elements comprise sulfur (S). Also, it is more preferable that the at least one or two or more contained elements comprise carbon (C).

Moreover, it is preferable that the noble metal-coating layer has a theoretical film thickness of 20 nanometers (nm) or more and 300 nanometers (nm) or less.

It is also preferable that oxygen elements are detected on the surface of the noble metal-coating layer.

It is also preferable that copper (Cu) is detected on the surface of the noble metal-coating layer.

It is also preferable that the core material is a copper alloy containing 0.003 mass % or more and 0.2 mass % or less of phosphorus (P).

It is also preferable that the core material is a copper alloy containing at least one or two or more members selected from platinum (Pt), palladium (Pd), and nickel (Ni) in a total amount of 0.1 mass % or more and 2 mass % or less.

It is also preferable that the core material is a copper alloy containing 0.1 mass ppm or more and 10 mass ppm or less of hydrogen.

Meanwhile, it is preferable that the palladium (Pd) cavitating layer or the palladium (Pd) cavitated layer is a stretched wet plating layer.

The grounds for the existence of each component are described below.

### (Basic Structure)

As for the palladium (Pd) cavitated layer of the present invention, when one or two or more contained elements having a low melting point are released from the palladium (Pd) cavitating layer, the palladium (Pd) cavitating layer becomes a palladium (Pd) cavitated layer, which has a shell-like structure. Since the palladium (Pd) cavitated layer is originally thin, when this layer is divided into fine particles, palladium (Pd) becomes an aggregate of several or several tens of palladium (Pd) atoms. The shell-like palladium (Pd) is strongly affected by the electromagnetic field because the bonding strength between the palladium (Pd) atoms is weak. Thus, the palladium (Pd) atoms are rearranged in the interface of the core material to form together with copper (Cu) atoms a stable palladium (Pd) concentrated layer.

The one or two or more contained elements having a low melting point in this case comprise at least one or two or more contained elements selected from Group 13 to 16 elements and oxygen elements. In the palladium (Pd)-coated copper wire for bonding of the present invention, the one or two or more contained elements selected from Group 13 to 16 surface-active elements and oxygen elements were selected as elements that are easily released from the layer in which they coexist with palladium (Pd), and form a palladium (Pd) cavitating layer. Moreover, these contained elements modify the surface of the molten copper.

The reason for using either a palladium (Pd) cavitating layer or a palladium (Pd) cavitated layer in the present invention is that the above palladium (Pd) cavitated layer maybe formed before a molten ball is formed. For example, after a palladium (Pd) cavitating layer is formed, during a general intermediate heat treatment process of copper wire materials between the so-called primary wire-drawing process and secondary wire-drawing process, the one or two or more contained elements can be extracted from the palladium (Pd) cavitating layer in which the above contained elements are finely dispersed. Moreover, since the palladium (Pd) cavitating layer is thin, a palladium (Pd) cavitated layer from which the one or two or more contained elements are removed can also be formed during the secondary wire-drawing process and the final tempering heat treatment process. In this case, either a palladium (Pd) cavitated layer from which the above contained elements are completely removed, or a palladium (Pd) cavitated layer from which part of the above contained elements are removed can be formed.

The presence or absence of a palladium (Pd) cavitating layer or a palladium (Pd) cavitated layer in the present invention can be confirmed by examining the distribution of the above contained elements in the interface of the core material and the surface of the wire. More specifically, even if no contained element is present in the palladium (Pd) coating, when the interface of the core material shows a high content, the presence of a palladium (Pd) cavitating layer or a palladium (Pd) cavitated layer is estimated. This is because, despite that the contained elements do not undergo surface segregation with the core material, when the interface of the core material shows a high content of the contained elements, it is estimated that the high content is derived from the contained elements released from the palladium (Pd) cavitating layer.

### (Contained Element)

It is preferable that the one or two or more specific contained elements of the present invention comprise one or two or more elements selected from sulfur (S), carbon (C), phosphorus (P), boron (B), silicon (Si), germanium (Ge), arsenic (As), selenium (Se), indium (In), tin (Sn), antimony (Sb), tellurium (Te), bismuth (Bi), and oxides thereof. It is more preferable that the above contained elements comprise sulfur (S), phosphorus (P), or carbon (C). In particular, a combination of sulfur (S) and one or more other contained elements is still more preferable.

Moreover, in the present invention, the palladium (Pd) cavitating layer containing one or two or more contained elements, which are selected from the group consisting of Group 13 to 16 surface-active elements, such as sulfur (S), phosphorus (P), boron (B), and carbon (C), and oxygen elements, maybe an eutectoid plating layer or an amorphous alloy layer, or the like, of palladium (Pd)-sulfur (S), phosphorus (P), boron (B), carbon (C), or the like. Plating of a laminated structure having alternating layers may also be used. Moreover, a copper (Cu) diffusion layer can be provided in one layer among, or a part of all palladium (Pd) cavitating layers by changing the drawing conditions, or the conditions for intermediate heat treatment or final heat treatment. However, with a palladium (Pd) cavitating layer using the abovementioned amorphous alloy and the like, a fine palladium (Pd) concentrated layer can be obtained during the formation of a molten ball. Eutectoid plating is performed by wet plating, such as electroplating, electroless plating, pulse plating, PR plating, and the like.

In the process of forming the palladium (Pd) cavitating layer of the present invention containing the one or two or more specific contained elements, the one or two or more specific contained elements can be interposed in a palladium (Pd)-deposited layer deposited from the vapor or liquid phase. Thereby, when the palladium (Pd) cavitating layer is subjected to heat treatment or strong wire drawing, the formation of metallic bonds between the palladium (Pd) deposition particles can be inhibited. Moreover, when a molten ball is formed, the palladium (Pd) cavitating layer has been converted into a palladium (Pd) cavitated layer, and the palladium (Pd) concentrated layer can be uniformly dispersed on the surface of the molten ball.

Secondarily, these contained elements interact with the copper (Cu) surface faster than palladium (Pd) during the formation of a FAB, and generates a large convection of the molten copper ball. Moreover, the surface activity of copper (Cu) melted below the palladium (Pd) cavitated layer having a high melting point in which copper (Cu) is not diffused is reduced. In such a state, the palladium (Pd) atoms in the form of fine particles formed from the palladium (Pd) cavitated layer and the molten copper (Cu) atoms interact with each other in the interface of the core material, and a stable palladium (Pd) concentrated layer is formed. Since the palladium (Pd) concentrated layer is immediately solidified, it is not melted into the molten copper (Cu) having a low melting point. As a result, the palladium (Pd) concentrated layer having a high melting point can be retained on the surface of the molten copper (Cu).

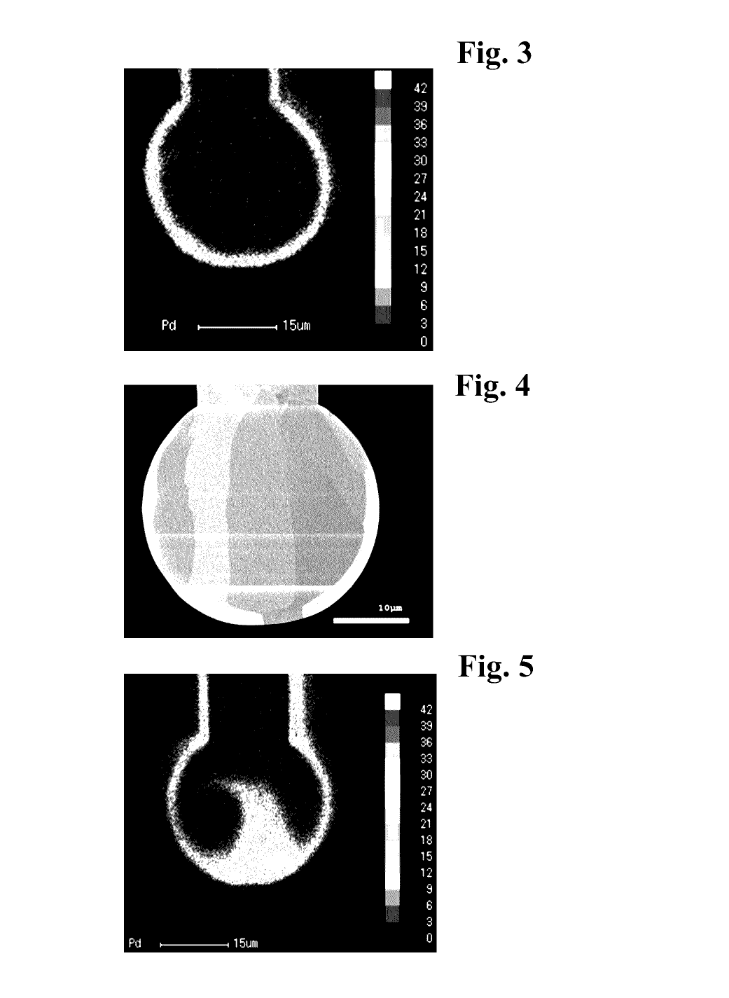

Oxygen elements (O) can be contained in the form of oxides of the abovementioned Group 13 to 16 surface-active elements. Moreover, when appropriate tempering heat treatment is applied to the noble metal-coated copper wire, oxygen elements are detected before copper (Cu) is detected on the surface of the noble metal-coating layer. Similar to sulfur (S), phosphorus (P), selenium (Se), or tellurium (Te), the oxygen elements on the surface have the effect of steering the direction of the large convection from the center of the wire toward the circumferential direction, as shown in FIG. 3.

Meanwhile, the oxygen elements (O) on the surface are detected as a concentrated layer from the surface, even if there is no gold (Au) ultra-thin stretched layer or copper (Cu) deposition layer, or even if a carbon (C) layer is present, as shown in FIG. 2. Accordingly, the oxygen elements (0) on the surface are considered to bind to palladium (Pd).

In wet plating, carbon (C) can be contained in a plating solution as an alcohol, a stabilizing agent, a surfactant, a brightener, or the like. Carbon (C) is preferably derived from an alcohol that decomposes at the temperature of the molten copper, or from a surfactant of a chain polymer compound. In dry plating, carbon (C) can be contained in a master alloy of the Group 13 to 16 surface-active elements mentioned above. Carbon (C) has the following effects: it lets the palladium (Pd) concentrated layer on the surface of the molten copper float on the large convection, prevents oxidation of the molten ball, and delays the melting thereof. Furthermore, carbon (C) is preferable because it does not alloy with palladium (Pd).

In the present invention, similar to the oxygen elements stated above, certain contained elements, namely sulfur (S), phosphorus (P), selenium (Se), or tellurium (Te), in the palladium (Pd) cavitating layer of the noble metal-coated copper wire also has the effect of steering the direction of the large convection from the center of the wire toward the circumferential direction when a molten ball is formed, as shown in FIG. 3. Furthermore, these low-melting-point metal elements are preferable because they do not alloy with palladium (Pd).

Sulfur is particularly preferable because it forms a surface phase of Cu₂S on the surface of the molten copper ball, reduces the surface tension of the molten copper ball, and blocks the incorporation of oxygen elements in the air; thus, the film thickness of the palladium (Pd) cavitated layer can be easily adjusted. Further, phosphorus (P) is more preferable because it forms phosphorus oxide volatile at 350° C., improves the flow of the molten ball, and blocks the incorporation of oxygen elements.

According to the experimental results of the present inventors, to arrange the above contained elements in the stronger order in terms of action regarding the palladium (Pd) concentrated layer, the order is sulfur (s)>phosphorus (P)>carbon (C), and the like. Sulfur (S) having a low melting point, and then phosphorus (P), more effectively modify the surface of copper (Cu) and have a more powerful action to prevent the movement of copper (Cu) atoms, in comparison to carbon (C), and the like. In particular, sulfur (S), which has a high surface activity, most effectively modifies the surface of the copper (Cu) of the core material, or active copper (Cu) in the outermost surface layer.

Since the diameter of the bonding wire is small, and the noble metal-coating layer is thin, it is impossible to directly measure the content of these contained elements; however, the content of these contained elements is preferably roughly 5 to 2,000 mass ppm, and more preferably 10 to 1,000 mass ppm, based on the palladium (Pd) cavitating layer.

It is preferable that the palladium (Pd) cavitating layer of the palladium (Pd)-coated copper wire for bonding of the present invention contains at least one or two or more members selected from sulfur (S), phosphorus (P), selenium (Se), tellurium (Te), and carbon (C) in a total amount of 30 mass ppm or more and 700 mass ppm or less (however, the phosphorus (P) content is 20 mass ppm or more and 800 mass ppm or less), and more preferably 50 mass ppm or more and 400 mass ppm or less.

These contained elements can be suitably selected depending on the thickness of the palladium (Pd) cavitating layer and the formation method thereof; however, it is more preferable that the palladium (Pd) cavitating layer contains 30 mass ppm or more and 300 mass ppm or less of sulfur (S). In particular, it is most preferable that sulfur (S) is contained in an amount of 80 mass ppm or more and 200 mass ppm or less. This is because it is easy to form a palladium (Pd) cavitated layer in the palladium (Pd) cavitating layer by heat transfer in an atomic state, not by thermal diffusion.

The content of these contained elements is a theoretical conversion value from the total content thereof in the noble metal-coated copper wire on the premise that the total content is contained in an ideal palladium (Pd) stretched layer. The sulfur (S) content is a theoretical conversion value that does not take into consideration whether sulfur (S) is derived from the air or not. Further, the phosphorus (P) content is a theoretical conversion value on the premise that phosphorus derived from the core material is excluded, and there is no volatile component. Moreover, the oxygen element content on the surface in the present invention is an estimated value determined from the mass of oxide and the mass equivalent of the concentrated layer. Therefore, this value does not always match actual analysis results of the elemental concentration at a specific place in the depth direction.

As for the other contained elements, i.e., boron (B), silicon (Si), germanium (Ge), arsenic (As), indium (In), tin (Sn), antimony (Sb), and bismuth (Bi), when a molten ball is formed, the direction of a large convection is directed from the circumferential direction to the center of the wire; therefore, as shown in FIG. 7, in a conventional palladium (Pd) stretched layer, these contained elements tend to entrain the palladium (Pd) layer into the inside of the molten ball. However, according to the palladium (Pd) cavitated layer of the present invention, it was found that these elements also formed a palladium (Pd) cavitated layer.

Of these, low-melting-point metals, such as tellurium (Te), selenium (Se), indium (In), tin (Sn), and bismuth (Bi), and oxides thereof are preferable because they are elements that reduce the surface entropy in the vicinity of the melting point of the molten copper, so that the temperature coefficient of surface tension can be positive. Moreover, boron (B), and the like are preferable because they do not alloy with palladium (Pd).

Examples of tellurium salts for wet plating include ammonium tellurate, potassium tellurate, sodium tellurate, telluric acid, potassium tellurite, sodium tellurite, tellurium bromide, tellurium chloride, tellurium iodide, tellurium oxide, and the like. Further, examples of selenium salts include potassium selenate, sodium selenate, barium selenate, selenium dioxide, potassium selenite, sodium selenite, selenious acid, selenium bromide, selenium chloride, selenium oxide, sodium hydrogen selenite, and the like.

The contained elements in the present invention can be used, for example, as general compounds, such as borates, in combination with a palladium (Pd) electrolysis plating bath or a palladium (Pd) electroless-plating bath. Moreover, the deposit from such baths can be provided in one layer of the laminated structure. When eutectoid plating is performed in such baths, fine particles in which the contained elements are uniformly dispersed on the deposited palladium (Pd) crystallites are obtained.

Moreover, since the contained elements in the present invention do not interact with each other in the palladium (Pd) cavitating layer until a molten ball is formed, various elements can be used in combination. Examples of the combination include sulfur (S) and phosphorus (P) or tellurium (Te); oxygen elements and one or two or more members selected from sulfur (S), phosphorus (P), tellurium (Te), and carbon; phosphorus (P) and tellurium (Te) or selenium (Se); carbon (C) and boron (B); and the like. Further, indium (In), tin (Sn), bismuth (Bi), and germanium (Ge) alloy can be sputtered to form a palladium (Pd) cavitating layer.

Furthermore, palladium (Pd) has a characteristic of absorbing hydrogen, as stated above. Intermediate annealing after primary wire drawing, and dry plating can be performed in a hydrogen atmosphere. Moreover, palladium (Pd) can be deposited by wet plating. The palladium (Pd) deposit, in which such contained elements are finely dispersed, contains hydrogen therein; however, the palladium (Pd) cavitating layer is thin, and therefore, the hydrogen does not affect the metal-coated copper wire. Therefore, when secondary wire drawing is performed while hydrogen is contained and without performing an intermediate heat treatment after primary wire drawing or baking treatment, there is an effect that the palladium (Pd) atoms in the palladium (Pd) cavitated layer are less likely to be thermally diffused during the formation of a molten ball. For dry plating, magnetron sputtering and ion plating are more preferable than vacuum deposition.

Moreover, it is preferable that the noble metal-coated copper wire contains 0.1 mass ppm or more and 10 mass ppm or less of hydrogen. In the present invention, the amount of hydrogen contained in the core material and the amount of hydrogen contained in the noble metal-coated copper wire are almost equivalent. It is more preferable that the noble metal-coated copper wire contains 0.3 mass ppm or more and 6 mass ppm or less of hydrogen. Most of the hydrogen in the noble metal-coated copper wire is derived from the copper alloy of the core material. The analysis of hydrogen in the noble metal-coated copper wire of the present invention can be performed using a thermal desorption analysis method (Journal of the Japan Copper and Brass Research Association, vol. 36 (1996) page 144, Isamu Sato, et al. “Gas Discharge Characteristics of Oxygen-Free Copper,” Journal of Japan Research Institute for Advanced Copper-Base Materials and Technologies, vol. 43, No. 1 (2004) page 99, Mikihiro Sugano, et al., “Thermal Desorption Analysis of Hydrogen in Copper and Copper Alloy,” and the like), in terms of atomic percent or mass percent.

### (Terms)

In the present invention, the term “theoretical film thickness” means a film thickness determined on the assumption that the cross-section of a bonding wire immediately after dry plating or wet plating is a complete circle, and this cross sectional circle is double- or triple-coated with palladium (Pd) or gold (Au) concentrically, and that the diameter of the subsequent secondary wire drawing is supposed to be reduced at the same ratio as the diameter reduction ratio of the wire diameter. The term “theoretical film thickness” is a concept created because, the coating layer being extremely thin, the surface shape of the core wire or the coated core wire changes due to the abrasion of diamond dies, and the film thickness of the outermost gold (Au) ultra-thin stretched layer, and the like, is extremely thin so that it cannot be actually measured.

For example, the ratio of nickel (Ni) or gold (Au) in the entire bonding wire is determined by chemical analysis using a gravimetric analysis method. Then, a film thickness is calculated from the determined value on the assumption that the cross-section of the bonding wire is a complete circle, and that the uppermost surface of the wire diameter is uniformly coated with nickel (Ni) or gold (Au). This film thickness is the theoretical film thickness. The case of a thin palladium (Pd) cavitating layer was also confirmed in the same manner. In the order of nanoscale, an actual bonding wire has an uneven surface, and therefore, the theoretical film thickness value may be smaller than the atomic radius of Ni, Au, and the like. As for the film thickness of the gold (Au) ultra-thin stretched layer, gold (Au) atoms are considered to be distributed quantum-theoretically.

The term “layer” used in the present invention is also a concept created because the film thickness is so extremely thin that it cannot be actually measured. That is, in the case of the uppermost gold (Au) ultra-thin stretched layer and the palladium (Pd) cavitating layer, regions in which fine particles of gold (Au) and palladium (Pd) are present are conveniently referred to as “layers.” The amount of the contained elements contained in these layers is also a theoretical value. Since these layers are thin, both or one of the copper (Cu) of the core material and the oxygen elements can be detected on the surface through the noble metal-coating layer. This is also one of the characteristics of the present invention.

In the “palladium (Pd) cavitating layer” before a molten ball is formed in the noble metal-coated copper wire of the present invention, the contained elements may be detected in the palladium (Pd) layer by Auger electron spectroscopy. However, the palladium (Pd) cavitated layer is not entrained into the inside of the “palladium (Pd) concentrated layer” in the bottom of the solidified ball, and there is no large void. On the other hand, part of the region in which the copper (Cu) diffusion layer is present is united with the molten copper ball, and melted into the molten copper ball. Considering the above, it was assumed that, for the “palladium (Pd) concentrated layer” present on the surface of the solidified ball, the palladium (Pd) coating layer was divided.

For example, when a noble metal-coated copper wire obtained by electroless plating of a Pd-8 mass % P alloy is first-bonded to an aluminum pad, and the surface of the solidified ball is analyzed, high-concentration phosphorus (P) is not detected in the “palladium (Pd) concentrated layer.” The “coating” layer of the present invention is a layer deposited from the vapor or liquid phase.

According to the noble metal-coated copper wire for ball bonding of the present invention, a method for uniformly forming a palladium (Pd) concentrated layer on the surface of a FAB, particularly, a method for uniformly forming a palladium (Pd) concentrated layer on the surface of a FAB by wet plating using a palladium (Pd) cavitating layer in which predetermined one or two or more specific low-melting-point contained elements are finely dispersed, is also disclosed. Furthermore, a method for first bonding of the wire of the present invention to an aluminum pad is also disclosed.

### (Palladium Cavitating Layer)

In the present invention, the palladium (Pd) cavitating layer is stretched, because one or two or more contained elements selected from Group 13 to 16 surface-active elements and oxygen elements are finely and uniformly dispersed in the palladium (Pd) layer, without forming a solid solution. Due to the fine and uniform dispersion, when these contained elements are released, a palladium (Pd) cavitated layer, which is easily dispersed in the form of fine particles on the surface of the molten ball, can be formed. The palladium (Pd) cavitated layer is observed as a trace of a palladium (Pd) concentrated layer carried by the flow of a large convection in the solidified ball.

That is, the palladium (Pd) cavitating layer of the present invention means a palladium (Pd) coating layer that is to be cavitated and divided during FAB formation at the latest. The contained elements contained in the palladium (Pd) cavitating layer can be contained in the palladium (Pd) layer or the laminated structure by wet plating, dry plating, molten salt plating, or the like. Further, the oxygen elements, which are gas components, can be intentionally incorporated from the oxides or from the air or water, together with the deposit.

In the stretched palladium (Pd) coating layer, the palladium (Pd) crystal grains are drawn by secondary wire drawing through diamond dies, and high mechanical strain remains in the palladium (Pd) crystal grains. This high strain state is relieved to some extent by the final heat treatment. In this case, the contained elements generally form a palladium (Pd) cavitating layer through the process of secondary wire drawing and final heat treatment. The noble metal-coated copper wire for ball bonding of the present invention is completed in this manner.

Copper (Cu) wires coated with palladium (Pd) are more resistant to oxidation than pure copper (Cu) wires. In the present invention, due to the presence of the oxidation-resistant palladium (Pd) cavitating layer, the core material is not sulfurized by corrosive gas in the air, such as sulfur and chlorine. Therefore, similar to a known core material composition comprising a copper alloy having a copper (Cu) purity of 99.9 mass % or more, the noble metal-coated copper wire for ball bonding of the present invention is bonded to an aluminum pad while the molten ball has a true spherical shape. Moreover, ultrasonic bonding as second bonding is also stable, as with a pure copper (Cu) wire.

The film thickness of the noble metal-coating layer in the present invention, particularly when the film thickness is a theoretical film thickness of 20 nanometers (nm) or more and 300 nanometers (nm) or less, can almost be ignored with respect to the wire diameter (10 μm or more and 25 μm or less) of the bonding wire. Therefore, when a molten ball is formed by a FAB, the molten ball is not affected by the film thickness of the coating layer.

A wet-type palladium (Pd) coating layer deposited from the liquid phase can be formed from an electroplating bath or an electroless-plating bath. A palladium (Pd) cavitating layer deposited from the liquid phase is preferable, since the deposition temperature on the wire surface is lower than that in the case of the vapor phase. Moreover, wet plating using an aqueous solution is more preferable, since a palladium (Pd) coating layer can be deposited at a relatively low temperature, namely from room temperature to 90° C. In wet plating, well-known additives may be added to the plating bath in order to finely disperse the palladium (Pd) deposit. The content of additives, such as a surfactant and a tempering compound, maybe much less than the content of contained elements. In spite of containing such less amounts of additives, denser amorphous palladium (Pd) crystallites can be deposited.

In the noble metal-coated copper wire for ball bonding of the present invention, the thickness of the noble metal-coating layer comprising a palladium (Pd) cavitating layer, or a palladium (Pd) cavitating layer and a gold (Au) ultra-thin stretched layer, is generally 0.5 micrometers (μm) or less. This is because the thicker the noble metal-coating layer is, the less likely the heat transfer of the contained elements in the atomic state occurs, and the molten copper ball tends to be unstable. Conversely, the thinner the noble metal-coating layer is, the more likely the transfer of the copper (Cu) of the core material in the atomic state occurs, and the copper can be expressed on the surface of the noble metal-coated copper wire.

It is preferable that the abovementioned palladium (Pd) cavitating layer has a theoretical film thickness of 20 nanometers (nm) or more and 300 nanometers (nm) or less. This is because this range is preferable for the copper (Cu) of the core material to be deposited on the wire surface by means other than thermal diffusion, and for oxygen elements (by Auger electron spectroscopy) to be expressed on the wire surface.

That is, if the theoretical film thickness is as overly thick as more than 300 nanometers (nm), the copper (Cu) deposition state is likely to be unstable. Conversely, if the theoretical film thickness is as overly thin as less than 20 nanometers (nm), the film thickness of the palladium (Pd) cavitating layer is overly thin, and it is difficult to form a uniform palladium (Pd) concentrated layer on the solidified ball. Therefore, it is preferable that the palladium (Pd) cavitating layer has a theoretical film thickness of 20 nanometers (nm) or more and 300 nanometers (nm) or less.

When the heat treatment temperature is raised or the heat treatment time is lengthened in the production process of the noble metal-coated copper wire, a copper (Cu) diffusion layer is first grown in the palladium (Pd) cavitating layer or the palladium (Pd) cavitated layer. If the heat treatment temperature is further raised, the copper (Cu) diffusion layer containing copper (Cu) dominates a large part of the noble metal-coating layer, and the palladium (Pd) cavitated layer consisting of palladium (Pd) disappears. Therefore, in the noble metal-coated copper wire of the present invention, in which the palladium (Pd) cavitating layer is thin, the temperature and time of the final heat treatment are important, depending on the composition of the core material used, the type of palladium (Pd) cavitating layer, and the like.

When a FAB is bonded to an aluminum pad by first bonding, the noble metal-coating layer on the wire surface of the present invention disappears in the bonding part. Moreover, this layer disappears in the bonding part during ultrasonic bonding as second bonding. As a result, a palladium (Pd) concentrated layer depending on the film thickness of the palladium (Pd) cavitating layer can be uniformly dispersed in the bonding interface, and the deterioration of the bonding interface can be delayed.

As stated above, when the contained elements are released from the palladium (Pd) cavitating layer, the palladium (Pd) cavitating layer becomes a palladium (Pd) cavitated layer, which is mechanically more fragile to a degree corresponding to the amount of the contained elements released. Moreover, the palladium (Pd) cavitated layer is divided into a solid phase portion and a liquid phase portion by the large convection of the molten ball. On the other hand, the palladium (Pd) cavitating layer can be recognized as an aggregate of the palladium (Pd) fine particles, according to the deposition form. Therefore, the palladium (Pd) cavitated layer in the solid phase portion is melted and solidified on the surface of the large convection of the molten copper (Cu), and forms a palladium (Pd) concentrated layer having a high melting point on the surface of the molten ball. This palladium (Pd) concentrated layer becomes uniformly distributed over the entire surface of the molten ball in accordance with the growth of the molten ball.

On the other hand, the contained elements in the palladium (Pd) cavitating layer are present in the form of small particles or atoms in the palladium (Pd) cavitating layer, according to the deposition form. The release of the contained elements proceeds faster than the formation of an interdiffusion region of the copper (Cu) of the core material and palladium (Pd). Moreover, a phenomenon in which copper (Cu) atoms entered the palladium (Pd) cavitated layer in which the contained elements were released was not observed. On the other hand, a phenomenon in which copper (Cu) atoms were deposited on the palladium (Pd) cavitated layer was observed. In the palladium (Pd) cavitating layer, residual hydrogen may be absorbed or alloyed, as stated above. This hydrogen is considered to be the remainder of what was released by the above secondary wire-drawing process and final tempering heat treatment process.

The palladium (Pd) cavitating layer can be formed by wet plating or dry plating. Both can be combined to form a laminated structure. In wet plating, electroplating or electroless plating can be used for formation. Both can be used in combination, or two types of palladium (Pd) electroplating (including eutectoid plating) can be performed to form a laminated structure. Furthermore, alternating electrolytic plating with pulse current and the like can also be performed.

When the palladium (Pd) cavitating layer has a laminated structure, the lower layer of the palladium (Pd) cavitating layer can be formed by nickel (Ni) plating, such as Pd-Ni alloy plating, Ni-S alloy plating, Ni-P alloy plating, or the like. Furthermore, the palladium (Pd) cavitating layer can have a laminated structure, such as a layered structure having three or more layers comprising a pure palladium (Pd) plating layer, a palladium (Pd) layer in which one or two or more contained elements selected from Group 13 to 16 surface-active elements and oxygen elements are finely dispersed, and a Pd-Ni alloy plating layer.

The palladium (Pd) cavitating layer in the noble metal-coated copper wire of the present invention is not metallurgically in an alloy state, and palladium (Pd) and one or two or more contained elements selected from Group 13 to 16 surface-active elements and oxygen elements are independent from each other at the crystal grain level. For example, the Group 13 to 16 surface-active elements and the oxygen element can be in the form of oxides. This is because, in an alloy state uniformly dissolved metallurgically, the contained elements cannot be singly separated from the palladium (Pd) cavitating layer.

When a molten ball is formed in the present invention, a large convection is generated due to the surface tension. The palladium (Pd) cavitated layer, from which the contained elements are released, floats on the molten ball, and the solidified cavitated layer slowly moves along the flow of the large convection. When the entire molten ball is solidified in the noble metal-coated copper wire of the present invention, a uniform palladium (Pd) concentrated layer, in which a trace of the convection remains, is formed on the surface.

For example, when the large convection flows from the bottom to the top of the central axis of the wire and, furthermore, from the circumference of the wire to the outer periphery, a trace of the flowing convection remains in the bottom of the solidified ball. In this case, the palladium (Pd) concentrated layer can be more stably distributed on the spherical surface of the molten ball than when the convection flows in an opposite direction. When the large convection flows in the opposite direction, its trace remains in the upper cross-section of the solidified ball. In this case, the molten ball tends to be dislocated from the axial center of the noble metal-coated copper wire, and to be eccentric. If the palladium (Pd) concentrated layer becomes thick, small voids are likely to be formed. If palladium (Pd) concentrated layers are stacked together to become overly thick, a large void is formed, and bonding to an aluminum pad is failed.

### (Gold (Au) Ultra-Thin Stretched Layer)

In the present invention, a gold (Au) ultra-thin stretched layer can be used as the noble metal-coating layer. When a gold (Au) ultra-thin stretched layer is used, the palladium (Pd) cavitating layer is held between the gold (Au) layer and the core material, and strong wire drawing is performed, so that the one or two or more contained elements contained in the palladium (Pd) cavitating layer can be thinly and uniformly dispersed in the palladium (Pd) cavitating layer. This is because the stretchability of the gold (Au) ultra-thin stretched layer is superior to that of the palladium (Pd) cavitating layer.

Even if the film thickness of the gold (Au) ultra-thin stretched layer during secondary wire drawing is a theoretical film thickness equal to or less than the atomic radius of gold (Au), gold (Au) can be detected by Auger electron spectroscopy. This specifically indicates that the gold (Au) of the gold (Au) ultra-thin stretched layer fills uneven grooves on the wire surface, and is 99.99 mass % or more of high purity gold. This also indicates that the gold (Au) ultra-thin stretched layer under secondary wire drawing follows the palladium (Pd) cavitating layer.

Moreover, the gold (Au) ultra-thin stretched layer can be present in the outermost surface to stabilize the spark current. Furthermore, due to the presence of a gold (Au) ultra-thin stretched layer, the palladium (Pd) cavitating layer can be efficiently stretched during secondary wire drawing, and the dispersion state of the one or two or more contained elements in the palladium (Pd) cavitating layer can be stabilized.

When a gold (Au) ultra-thin stretched layer is present, the one or two or more contained elements selected from Group 13 to 16 surface-active elements, such as sulfur (S), phosphorus (P), boron (B) and carbon (C), and oxygen elements are considered to be diffused in the gold (Au) ultra-thin stretched layer as well, which has a high chemical reactivity, due to the final heat treatment. Therefore, the surface of the noble metal-coated copper wire is modified to be chemically inert. On the other hand, as stated above, sulfur (S) coexists with gold (Au) and is fixed to the wire surface, and thus, the active gold (Au) ultra-thin stretched layer is also modified to be chemically inert.

When the film thickness of gold (Au) is as thick as several hundreds of nanometers sufficient for actual measurement by depth direction analysis using an Auger electron spectrometer, a lump of melting heat is previously formed in the gold (Au) layer, which has a lower melting point than copper (Cu). Therefore, the copper (Cu) molten ball becomes unstable dragged by the golden (Au) lump. Moreover, the golden (Au) lump wets the gold (Au) film on the wire surface in the root of the molten ball, and climbs up on the unmelted wire surface due to the surface tension of the molten ball, and an erratic ball is likely to be formed. Therefore, the film thickness of gold (Au) is preferably less than 20 nanometers.

The thickness of the gold (Au) ultra-thin stretched layer is more preferably a theoretical film thickness of 3 nanometers (nm) or less. Even if the gold (Au) ultra-thin stretched layer has a theoretical film thickness of 3 nanometers (nm) or less, the destination of spark discharge during FAB formation does not vary. The thickness of the gold (Au) ultra-thin stretched layer is even more preferably a theoretical film thickness of 2 nanometers (nm) or less. Even if the thickness is a theoretical film thickness of 2 nanometers (nm) or less, gold (Au) fine particles are dotted on the palladium (Pd) cavitating layer on the surface of an actual noble metal-coated copper wire. Since the electrical conductivity of gold (Au) is higher than that of palladium (Pd), it is understood that spark discharge reaches the gold (Au) fine particles to start the formation of a molten ball. The lower limit of the thickness of the gold (Au) ultra-thin stretched layer is preferably 0.1 nanometers (nm) or more.

When a gold (Au) ultra-thin stretched layer is present, sulfur (S) tends to be easily formed to the same depth, as shown in FIG. 2. That is, it can be said that sulfur (S) in the palladium (Pd) cavitating layer can be combined with sulfur (S) on the gold (Au) ultra-thin stretched layer so that the sulfur (S) is concentrated on the gold (Au) ultra-thin stretched layer. When a gold (Au) ultra-thin stretched layer is present, even if the copper (Cu) of the core material is deposited on the surface, sulfide (Cu₂₅) is formed, and thus, the surface state of the noble metal-coated copper wire is stabilized.

### (Copper (Cu) Diffusion Layer) 8

As described above, the copper (Cu) diffusion layer is a region in which the copper (Cu) of the core material is diffused in the palladium (Pd) cavitating layer. During the formation of a molten ball, the copper (Cu) diffusion layer flows in the large convection of the surface of the molten ball and is incorporated into the inside of the molten ball. Accordingly, it is preferable to make the thickness of the copper (Cu) diffusion layer as thin as possible. The thickness of the copper (Cu) diffusion layer is preferably ⅓ or less, more preferably ¼ or less, of the entire thickness of the palladium (Pd) cavitating layer. When a nickel (Ni) intermediate layer is provided, the thickness of the copper (Cu) diffusion layer can be reduced.

It is preferable that a nickel (Ni) intermediate layer is provided in the palladium (Pd) cavitating layer, because the thickness of the copper (Cu) diffusion layer, which contains copper (Cu), can be reduced. However, when the nickel (Ni) intermediate layer is thick, the shape of the solidified ball tends to be unstable, and the solidified ball tends to be hard. Therefore, it is preferable that the nickel (Ni) intermediate layer has a theoretical film thickness of 40 nanometers (nm) or less, and more preferably 20 nanometers (nm) or less.

The nickel (Ni) intermediate layer can have a laminated structure. Further, the layer may contain at least one or two or more contained elements selected from Group 13 to 16 surface-active elements and oxygen elements. The nickel (Ni) intermediate layer can contain sulfur (S) or phosphorus (P) in a part of the monolayer or laminated structure by wet plating. It is more preferable that the nickel (Ni) intermediate layer contains sulfur (S) or phosphorus (P), because a less amount of sulfur (S) or phosphorus (P) is transferred from the palladium (Pd) cavitating layer to the core material side, and the palladium (Pd) cavitating layer can be stably formed. In particular, it is even more preferable that the nickel (Ni) intermediate layer contains sulfur (S).

### (Core Material)

For the copper alloy of the core material, the type of additive element is suitably required, depending on the type and application of the required semiconductor device. The combination of additive elements and the amount thereof to be added can be suitably determined, depending on the thermal and mechanical properties required for bonding wires. On the other hand, the large convection on the surface of the molten ball is likely to form a turbulent flow when a small convection is generated. Therefore, a core material composition that can form a uniform molten ball is required. When alloying, it is preferable that additive elements described later are contained.

For example, in the present invention, a copper alloy containing 0.01 mass % or more and 2.0 mass % or less of phosphorus (P) is preferred. It is known that stable FAB can be formed when phosphorus (P) is present in copper (Cu) of a core material (Japanese Unexamined Patent Application Publication No. 2010-225722, and International Publication No. WO 2011/129256). In the present invention, it was also found that the flow of the large convection was improved, the smoothness of the divided palladium (Pd) cavitated layer was enhanced, and a uniform palladium (Pd) concentrated layer was distributed.

It is preferable that the copper alloy contains 0.001 mass % or more and 2.0 mass % or less of phosphorus (P). If the phosphorus (P) content is less than 0.001 mass o, this effect cannot be exhibited. In contrast, if the phosphorus (P) content is more than 2.0 mass %, the palladium (Pd) cavitating layer is not stable. Therefore, when phosphorus (P) is contained, the content thereof is preferably 0.001 mass % or more and 2.0 mass % or less, and more preferably 0.01 mass % or more and 1.6 mass % or less. When phosphorus (P) is selected, for the other metal components, elements can be suitably selected putting alloys of the existing prior art into consideration.

It is also possible to use a copper alloy containing 0.1 mass % or more and 2 mass % or less of platinum (Pt), palladium (Pd), or nickel (Ni). This is because the molten ball is stabilized, and the shrinkage cavities of the solidified ball are reduced. Another reason for this is that the wedge bonding strength of second bonding is stable. To arrange the metals in the order of preferability, the order is platinum (Pt)>palladium (Pd)>nickel (Ni). Among the three metals, platinum (Pt) is the most preferable.

However, the above effect is not exhibited if the content of the element of platinum (Pt), palladium (Pd), or nickel (Ni) is less than 0.1 mass %, whereas the molten ball becomes hard if their content is more than 2 mass %. Thus, it is preferable that the copper alloy contains 0.1 mass % or more and 2 mass % or less of platinum (Pt), palladium (Pd), or nickel (Ni). The platinum (Pt) content is more preferably in the range of 0.3 to 1 mass %. The palladium (Pd) content is more preferably in the range of 0.5 to 1.5 mass %. The nickel (Ni) content is more preferably in the range of 0.5 to 1 mass %. When a copper alloy containing a predetermined amount of platinum (Pt), palladium (Pd), or nickel (Ni) is used, the thickness of the palladium (Pd) cavitating layer can be further reduced.

It is also preferable to use an oxygen-free copper alloy containing 0.1 mass ppm or more and 10 mass ppm or less of hydrogen. This is because, in the present invention, the amount of hydrogen contained in the core material and the amount of hydrogen contained in the noble metal-coated copper wire are almost equivalent. As a result, the noble metal-coated copper wire contains 0.1 mass ppm or more and 10 mass ppm or less of hydrogen. This is because, when the palladium (Pd) layer having a high melting point is melted therein, such an oxygen-free copper alloy does not allow vapor to form due to binding with oxygen elements. Vapor is considered to cause voids. More preferred is an oxygen-free copper alloy containing 0.3 mass ppm or more and 5 mass ppm or less of hydrogen.

### Advantageous Effects of Invention

According to the noble metal-coated copper wire for ball bonding of the present invention, during the formation of a molten ball, the palladium (Pd) coating layer is reliably divided due to the palladium (Pd) cavitated layer; therefore, a palladium (Pd) concentrated layer can be uniformly formed on the surface of the FAB. Accordingly, even in the case of mass-produced bonding wires, first bonding of the FAB to an aluminum pad is stable.

Moreover, since the palladium (Pd) concentrated layer covers the entire surface of the molten ball, palladium (Pd) remains in the bonding interface between the aluminum pad and the copper ball, and the formation of AlCu intermetallic compounds can be delayed. Furthermore, when a gold (Au) ultra-thin stretched layer is present, spark current is stable even if the tip of the wire is slightly deformed. Therefore, spark current can be supplied to the noble metal-coated copper wire.

Even if one or two or more contained elements selected from Group 13 to 16 surface-active elements and oxygen elements remain in the palladium (Pd) cavitating layer, these contained elements first move during the formation of a molten ball, and thus, the molten ball does not become unstable. Further, similar to the case of oxygen elements, the contained elements, i.e., sulfur (S), phosphorus (P), selenium (Se), and tellurium (Te), have the effect of steering the direction of a large convection from the periphery of the upper portion of the wire to the circumferential direction when a molten ball is formed. Thus, there is also an effect of suppressing the eccentricity of the molten ball.

Furthermore, during wedge bonding as second bonding, these contained elements are released from the palladium (Pd) cavitating layer, and the active copper (Cu) of the core material is exposed; thus, bonding to the lead is performed while the palladium (Pd) concentrated layer is distributed. As a result, there is an effect of improving the bonding properties of the second bonding.

Moreover, according to the palladium (Pd)-coated copper wire of the present invention, the entrance of oxygen elements from the air is blocked by a palladium (Pd) cavitating layer, particularly by a palladium (Pd) cavitating layer containing one or two or more contained elements selected from Group 13 to 16 surface-active elements and oxygen elements, until a molten ball is formed. The denser the initial palladium (Pd) plating film that forms the palladium (Pd) cavitating layer is, the higher the effect of preventing the formation of an oxide film of copper oxide on the copper alloy of the core material is, in comparison to conventional pure palladium (Pd) layers. Moreover, the noble metal-coated copper wire for ball bonding of the present invention has a very thin noble metal-coating layer; therefore, mechanical bending, such as loop formation, can also be enhanced, as in conventional copper wires for ball bonding.

When a gold (Au) ultra-thin stretched layer is formed on the outermost surface of the wire, discharge current becomes stable. Further, even when wires are multi-wound, the wires do not adhere to each other. Consequently, the unwinding properties of the wires are improved. As an accompanying effect, the smoothness of the wire surface for the capillary is enhanced. Moreover, according to the noble metal-coated copper wire for ball bonding of the present invention, the gold (Au) ultra-thin stretched layer on the outermost surface of the wire is not removed from the palladium (Pd) coating layer. Therefore, even when bonding is repeated many times, copper (Cu) oxide does not adhere to the capillary; thus, the capillary is not contaminated.

### EXAMPLES

As shown in Table 1, the core materials used were obtained by adding or not adding platinum (Pt), nickel (Ni), or phosphorus (P) to oxygen-free copper (Cu) having different hydrogen contents and a purity of 99.99 mass % or more. The core materials were continuously casted, and rolled while performing pre-heat treatment, followed by primary wire drawing, thereby obtaining thick wires (diameter: 1.0 mm). Subsequently, the outer periphery of each thick wire was coated with a palladium (Pd) cavitating layer and a gold (Au) ultra-thin stretched layer shown in Table 1. The purity of gold (Au) in the ultra-thin stretched layer is 99.99 mass % or higher.

### Examples 1 to 3

A coating layer of a palladium (Pd)-sulfur (S) amorphous alloy was formed in the following manner. An ADP700 additive (manufactured by Electroplating Engineers of Japan Ltd.) was added in amounts of 0.1 g/L, 0.005 g/L, and 0.15 g/L to a commercially available palladium (Pd) electroplating bath (ADP700, manufactured by Electroplating Engineers of Japan Ltd.). The sulfur (S) concentration of the electroplating bath was adjusted to a medium concentration, a low concentration, and a high concentration, depending on the amount of the additive added. In each bath, an electric current was applied at a current density of 0.75 A/dm² to a copper wire having a diameter of 1.0 mm, and a coating layer of palladium (Pd)-sulfur (S) eutectoid plating was formed. The resulting three types of coated copper wires were each coated with gold (Au) to a predetermined thickness by magnetron sputtering.

Thereafter, baking treatment was not performed, continuous secondary wire drawing was performed through diamond dies, and tempering heat treatment was performed at 480° C. for 1 second. As a result, noble metal-coated copper wires for ball bonding having a diameter of 18 μm were obtained. These wires were regarded as Examples 1 to 3. The average diameter reduction rate is 6 to 20%, and the final linear velocity is 100 to 1,000 m/min.

The hydrogen concentrations of the noble metal-coated copper wires of Examples 1 to 3 were 0.5 mass ppm, 3 mass ppm, and 1 mass ppm, respectively, and the contained sulfur (S) concentrations of the palladium (Pd) cavitating layers were 170 mass ppm, 50 mass ppm, and 250 mass ppm, respectively.

### Example 4

A coating layer of a palladium (Pd)-phosphorus (P) amorphous alloy was formed in the following manner. First, nickel (Ni) electroplating was performed as base plating. In a Watts bath, an electric current was applied at a current density of 2 A/dm² to a copper wire having a diameter of 1.0 mm, and a 0.2-μm nickel (Ni)-coating layer was formed. Then, 0.2 g/L of phosphorous acid (H₃PO₃) was added to a commercially available palladium (Pd) electroplating bath (ADP700, manufactured by Electroplating Engineers of Japan Ltd.). In this bath, an electric current was applied at a current density of 0.75 A/dm² to the copper wire having a diameter of 1.0 mm, and a coating layer of a palladium (Pd)-phosphorus (P) amorphous alloy was formed. The subsequent procedures were performed in the same manner as in Example 1 to thereby produce a noble metal-coated copper wire for ball bonding of Example 4.

The hydrogen concentration of the noble metal-coated copper wire of Example 4 was 6 mass ppm, and the contained phosphorus (P) concentration of the palladium (Pd) cavitating layer was 420 mass ppm.

### Example 5

A coating layer of a palladium (Pd)-carbon (C)-boron (B)-containing alloy was formed in the following manner. A surfactant (2 mL/L; JS Wetter, manufactured by Electroplating Engineers of Japan Ltd.) and a predetermined amount of boron inorganic compound were added to a commercially available palladium (Pd) electroplating bath (ADP700, manufactured by Electroplating Engineers of Japan Ltd.). Further, a chain polymer brightener was added. In this bath, an electric current was applied at a current density of 0.75 A/dm² to a copper wire having a diameter of 1.0 mm, and a coating layer of palladium (Pd)-carbon (C)-boron (B) eutectoid plating was formed. The subsequent procedures were performed in the same manner as in Example 1 to thereby produce a noble metal-coated copper wire for ball bonding of Example 5.

The hydrogen concentration of the noble metal-coated copper wire of Example 5 was 0.3 mass ppm, and the concentrations of the contained elements in the palladium (Pd) cavitating layer were as follows: carbon (C): 630 mass ppm, and boron (B): 300 mass ppm.

### Examples 6 to 8

Coating layers of palladium (Pd)-selenium (Se), tellurium (Te), or sulfur (S) eutectoid plating were formed in the following manner. A predetermined amount of selenium (Se) compound or tellurium (Te) compound was added as a crystal regulator to a commercially available palladium (Pd) electroplating bath (ADP700, manufactured by Electroplating Engineers of Japan Ltd.). Further, the same sulfur (S) compound as that of Example 1 was added.

In each bath, an electric current was applied at a current density of 0.75 A/dm² to a copper wire having a diameter of 1.0 mm, and a coating layer of palladium (Pd)-selenium (Se) or tellurium (Te) eutectoid plating was formed. The subsequent procedures were performed in the same manner as in Example 1 to thereby produce noble metal-coated copper wires for ball bonding of Examples 6 to 8.

The hydrogen concentration of the noble metal-coated copper wire of Example 6 was 0.3 mass ppm, and the concentration of the contained element, i.e., selenium (Se), in the palladium (Pd) cavitating layer was 180 mass ppm. Moreover, in Example 7, the hydrogen concentration was 0.7 mass ppm, and the tellurium (Te) concentration was 680 mass ppm. Furthermore, in Example 8, the hydrogen concentration was 0.7 mass ppm, the sulfur (S) concentration was 90 mass ppm, the selenium (Se) concentration was 170 mass ppm, and the tellurium (Te) concentration was 170 mass ppm.

TABLE 1

| | | | | | | | | | Containing | | |
|---|---|---|---|---|---|---|---|---|---|---|---|
| | | | | Thickness of | | | | | element | | |
| | Core material | | Thickness of | Au ultra-thin | Containing element | | | | concentration of | Hydrogen | |
| | | Additive | Pd cavitating | stretched | concentration of wire | | | | Pd cavitating | concentration | |
| | 4N | element | layer | layer | (mass ppm) | | | | layer | of wire | |
| No. | Cu | (mass %) | (nm) | (nm) | S | P | C | Other | (mass ppm) | (mass ppm) | HAST test |
| Example 1 | Balance | Pt 0.5 | 50 | 2 | 3 | — | — | — | S 170 | 0.5 | ◯ |
| Example 2 | Balance | Ni 1 | 280 | 3 | 5 | — | — | — | S 50 | 3 | ◯ |
| Example 3 | Balance | Pt 0.2 + | 100 | 1 | 8 | — | — | — | S 250 | 1 | ◯ |
| | | Ni 1.2 | | | | | | | | | |
| Example 4 | Balance | P 0.02 | 40 | — | — | 210 | — | — | P 420 | 6 | ◯ |
| Example 5 | Balance | — | 70 | 2 | — | — | 13 | — | C 630 + B 30 | 0.3 | ◯ |
| Example 6 | Balance | Pd 0.5 | 130 | 4 | | | | Se 7 | Se 180 | 0.3 | ◯ |
| Example 7 | Balance | P 0.005 | 50 | 2 | | | | Te 10 | Te 680 | 0.7 | ◯ |
| Example 8 | Balance | P 0.04 | 60 | 1 | 2 | | | Se 3 + | S 40 + Se 170 + | 2 | ◯ |
| | | | | | | | | Te 3 | Te 170 | | |
| Comparative | Balance | — | 60 | 100 | 0.5 | — | — | — | — | 0 | X |
| Example 1 | | | | | | | | | | | |
| Comparative | Balance | — | 40 | — | — | — | — | — | Ni 20 | 11 | X |
| Example 2 | | | | | | | | | | | |

Here, the values of palladium in the cavitating layer and gold in the ultra-thin stretched layer shown in Table 1 were obtained as follows. About 1,000 m of a wire having a diameter of 18 μm was dissolved in aqua regia, and the concentrations of gold (Au) and palladium (Pd) in the solution were determined by a high-frequency inductively coupled plasma emission spectroscopy (ICPS-8100, manufactured by Shimadzu Corp.). Based on the determined concentrations, the above values were calculated as uniform film thicknesses in the wire diameter of the bonding wire. That is, they are conversion values by ICP chemical analysis.

About 100 m of each of the wires of Examples 1 to 8 was dissolved in aqua regia, and the contained element concentration of the solution was determined by using an inductively coupled plasma mass spectrometer (Agilent 8800, manufactured by Agilent Technologies Japan, Ltd.). However, the carbon (C) concentration of the wire of Example 5 was determined by taking 500 m (about 1 g) of the wire, and determining the carbon (C) concentration by a combustion method (CS844, manufactured by Leco Japan Corporation). The middle columns of Table 1 show the results.

The bonding wire of Example 1 was subjected to elemental analysis for each of the elements: palladium (Pd), copper (Cu), gold (Au), oxygen elements, and sulfur (S), in the depth direction using a scanning Auger electron spectrometer (MICROLAB-310D, manufactured by VG Scientific). Consequently, the analysis results shown in FIG. 2 were obtained.

As is clear from the analysis results in FIG. 2, depth-wise from the surface of the wire, from shallow to deep, the order was as follows: gold (Au) layer and oxygen element layer<sulfur (S) layer and copper (Cu) layer<carbon (C) layer<palladium (Pd) layer. The low concentration of gold (Au) means that the gold (Au) layer is an ultra-thin layer. Moreover, the oxygen elements in the surface layer are considered to bind to palladium (Pd). On the other hand, the carbon (C) layer is considered to be present in the palladium (Pd) layer. The amount of sulfur (S) is the total amount of sulfur (S) attached from the air and sulfur (S) released from the palladium (Pd) cavitating layer.

Subsequently, the bonding wire of Example 1 was treated with a fully automatic bonder ICONN ProCu ultrasonic device (manufactured by K&S) at a spark discharge voltage of 6,000 volts, thereby forming 1,000 molten balls (34 μm). All of the solidified balls had a white metallic luster similar to that of palladium (Pd).

When the entire surface of the ball was analyzed by a scanning Auger electron spectrometer (MICROLAB-310D, manufactured by VG Scientific), the ratio in terms of mass % was 90% Cu-10% Pd alloy. When the cross-section of the solidified ball was observed, a palladium (Pd) concentrated portion was not particularly observed in the bottom of the ball, and a palladium (Pd) concentrated layer was uniformly distributed. FIG. 3 shows a photograph of the cross-sectional distribution of palladium (Pd) in the bonding wire taken by an Auger electron spectrometer, and FIG. 4 shows a photograph of the cross-section of the same portion taken by a scanning electron microscope.

As is clear from FIG. 3, according to the palladium (Pd)-sulfur (S) electroplating alloy layer of the present invention, a palladium (Pd) concentrated layer of Cu-10 mass % Pd alloy is uniformly dispersed on the solidified ball. Further, as is clear from FIG. 4, according to the palladium (Pd)-sulfur (S) electroplating alloy layer of the present invention, the palladium (Pd) cavitated layer is divided, and the palladium (Pd) cavitated layer having a high melting point is not entrained in the inside of the molten copper; therefore, no large void is formed in the inside of the molten copper. It can be thus understood that when a FAB is bonded to an aluminum pad, palladium (Pd) is uniformly dispersed in the bonding interface with the aluminum pad, and the bonding strength is stable.

As for the other noble metal-coated copper wires for ball bonding of Examples 2 to 8, which are not shown in the figures, it was observed that a palladium (Pd) concentrated layer was uniformly distributed on the surface of each solidified ball, as in Example 1. In particular, in the noble metal-coated copper wire for ball bonding of Example 5, a palladium (Pd) concentrated layer was uniformly distributed on the surface of the solidified ball, even though the direction of a large convection in the upper portion of the wire was directed from the circumferential direction to the center of the wire. It can be understood from the above that a HAST test, described later, showed excellent results due to the effect that the palladium (Pd) cavitated layer was divided into the shape of wedges, and the palladium (Pd) cavitated layer remained on the surface of the molten copper ball.

### (Corrosion Test of Intermetallic Compound)

The wires of Examples 1 to 8 were treated with a fully automatic ribbon bonder ICONN ultrasonic device (manufactured by K&S) to produce 34 μm molten balls on an Al-1 mass % Si-0.5 mass % Cu alloy pad (thickness: 2 μm) on an Si chip (thickness: 400 μm) on a BGA substrate under the following conditions: EFO electric current: 60 mA, and EFO time: 144 microseconds. Then, 1,000 bondings were performed with a bonding diameter of 50 μm and a loop length of 2 mm.

In this case, in the Al-1 mass % Si-0.5 mass % Cu alloy pad on the chip, only adjacent bond parts are electrically connected. Moreover, adjacent wires electrically form together one circuit, and a total of 500 circuits are formed. Thereafter, the Si chip on the BGA substrate was sealed with resin using a commercially available transfer molding machine (GPGP-PRO-LAB80, manufactured by Dai-ichi Seiko Co., Ltd.).

These test pieces (Examples 1 to 8) were held at 130° C.×85 RH (relative humidity) for 200 hours using a HAST chamber (PC-R8D, manufactured by Hirayama Manufacturing Corporation). The electric resistance values of the 500 circuits were measured before and after holding. When there was at least one circuit in which the electric resistance value after holding was 1.1 times higher or more than the electric resistance value before holding, this case was noted as x; and when all of the 500 circuits showed a resistance value of less than 1.1 times, this case was noted as O. The right column of Table 1 shows the results. As is clear from the test results of the HAST test, all of the test pieces of Examples 1 to 8 of the present invention showed a resistance value of less than 1.1 times in all of the 500 circuits.

For contained elements other than those used in the Examples, namely silicon (Si), germanium (Ge), arsenic (As), indium (In), tin (Sn), antimony (Sb), and bismuth (Bi), a predetermined amount of a known compound was singly added to a palladium (Pd) electroplating bath (ADP700, manufactured by Electroplating Engineers of Japan Ltd.) in the same manner as in Example 1, and noble metal-coated copper wires for ball bonding were prepared. It was observed that in all of these wires, a palladium (Pd) concentrated layer was uniformly distributed on the surface of the molten ball, as in Example 5.

Moreover, about 200 mass ppm of germanium (Ge) and silica (SiO2) was mixed in a palladium (Pd) coating layer using a magnetron sputtering device (manufactured by Tanaka Denshi Kogyo K.K.), and evaluation was conducted in the same manner as in Example 4. Consequently, the same results as in Example 4 were obtained. The test results of the HAST test were also excellent.

### Comparative Example 1

A bonding wire was produced in the same manner as in Example 1, except that the film thickness was increased, and intermediate annealing and baking treatment was performed at 450° C. for 60 minutes after gold (Au) plating. This bonding wire was regarded as Comparative Example 1. In the bonding wire, the film thickness of the Au ultra-thin stretched layer was as thick as 100 nm, a half or more of the palladium (Pd) cavitating layer was a copper (Cu) diffusion layer, and there was a small copper (Cu) non-diffusion region. The hydrogen concentration of the bonding wire was less than 0.1 mass ppm, which was below the measuring limit. The sulfur (S) concentration was 5 mass ppm.

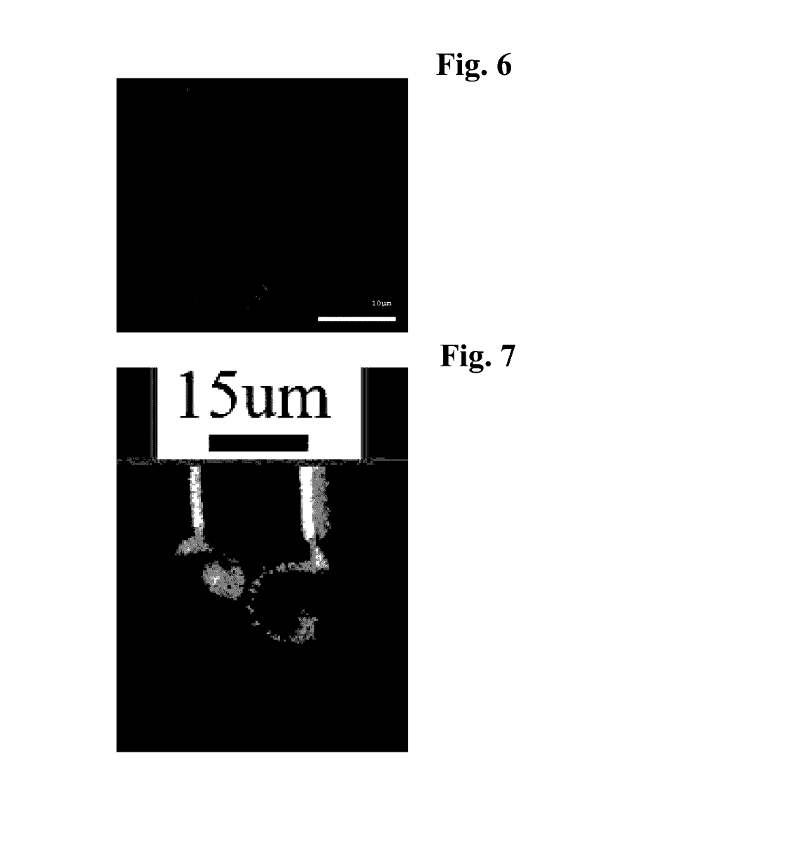

Further, molten balls were produced from the bonding wire of Comparative Example 1 in the same manner as in Example 1. FIG. 5 shows a photograph of the cross-sectional distribution of palladium (Pd) in the molten and solidified ball taken by an Auger electron spectrometer, and FIG. 6 shows a photograph of the cross-section of the same portion taken by a scanning electron microscope. More specifically, FIG. 5 shows an AES image taken by a scanning Auger electron spectrometer (MICROLAB-310D, manufactured by VG Scientific). FIG. 6 shows a scanning electron microscope (SEM) image taken by the same spectrometer.

As is clear from FIG. 5, in the palladium (Pd)-coated copper wire of Comparative Example 1, there is a trace that a small turbulent flow was produced in the right side of the root of the wire, that the palladium (Pd) concentrated layer had uneven tone, and that a part of the palladium (Pd) concentrated layer was melted into the inside of the molten ball. That is, the photograph of FIG. 5 suggests that since the small turbulent flow continuously changes depending on the conditions, palladium (Pd) cannot be uniformly dispersed on the molten ball.

As is clear from the photograph of the cross-sectional distribution of palladium (Pd) in FIG. 5, the palladium (Pd) concentrated layer flows into the inside of the molten ball due to a large convection flowing from the bottom of the molten ball. Further, as is clear from the cross-sectional photograph taken by a scanning electron microscope in FIG. 6, large and small voids are formed along the flow of palladium (Pd) having a high melting point.

### Comparative Example 2

A bonding wire was produced in the same manner as in Example 1, except that gold (Au) was not coated, intermediate annealing and baking treatment was performed at 450° C. for 60 minutes in a hydrogen atmosphere, a predetermined amount of a nickel (Ni) compound was added to a commercially available palladium bath for formation of the wire, and tempering heat treatment was performed at 600° C. for 1 second. This bonding wire was regarded as Comparative Example 2. Further, molten balls were produced from the bonding wire of Comparative Example 2 in the same manner as in Example 1. The hydrogen concentration of the bonding wire was 15 mass ppm. The nickel (Ni) concentration was 20 mass ppm.

As is clear from the photograph of the cross-sectional distribution of palladium (Pd) in the bonding wire taken by an Auger electron spectrometer shown in FIG. 7, a palladium (Pd) concentrated layer flows into the inside of the molten ball due to a large convection flowing from the upper portion of the molten ball to the root of the wire. This indicates that even though a palladium (Pd) cavitating layer is provided, the surface of the molten ball cannot be coated with the cavitated layer, and that the palladium (Pd) concentrated layer cannot be uniformly dispersed on the solidified ball, unlike the case of the present invention.

### (Contained Element Concentration in Comparative Examples)

About 100 m of each of the wires of Comparative Examples 1 and 2 were dissolved in aqua regia, and the sulfur (S) concentration and nickel (Ni) concentration of the solution were determined by an inductively coupled plasma mass spectrometer (Agilent 8800, manufactured by Agilent Technologies Japan, Ltd.). The middle column of Table 1 shows the contained element concentration (theoretical amount) in the palladium (Pd) cavitating layer converted from the results.

### (Corrosion Test of Intermetallic Compound)

The wires of Comparative Examples 1 and 2 were examined for the change in the electric resistance value of circuits before and after holding at a high temperature and a high humidity (130° C.×85 RH) in the same manner as in Examples 1 to 5. The wires of Comparative Examples 1 and 2 showed an increase in the electric resistance value of the circuits; this demonstrates that these wires are not suitable as bonding wires. The right column of Table 1 shows the results as symbol X.

### INDUSTRIAL APPLICABILITY

The noble metal-coated copper wire for ball bonding of the present invention can take the place of conventional gold alloy wires, and can be used for semiconductors, such as general ICs, discrete ICs, and memory ICs, as well as IC package for LEDs, IC package for automobile semiconductors, and the like, for which low cost is required in spite of high-humidity, high-temperature applications.

What is claimed is:

1. A noble metal-coated copper wire for ball bonding, with a wire diameter between 10 μm or more, and 25 μm or less, comprising:
a core material comprising a copper alloy having a copper purity of 98 mass % or higher, and a noble metal-coating layer formed on the core material;
wherein the noble metal-coating layer comprises:
a palladium cavitating layer containing palladium; at least one element selected from the group consisting of Group 13 to 16 elements or an oxygen element, the at least one element being finely dispersed in the palladium; and a diffusion layer formed of copper diffused into the palladium.

2. A noble metal-coated copper wire for ball bonding according to claim 1, wherein the noble metal-coating layer further comprises a gold ultra-thin stretched layer deposited on the palladium cavitating layer.

3. A noble metal-coated copper wire for ball bonding, with a wire diameter between 10 μm or more, and 25 μm or less, comprising:
a core material comprising a copper alloy having a copper purity of 98 mass % or higher, and a noble metal-coating layer formed on the core material;
wherein the noble metal-coating layer comprises:
a palladium cavitating layer containing palladium, at least one element selected from the group consisting of Group 13 to 16 elements or an oxygen element, the at least one element being finely dispersed therein, and
a nickel intermediate layer disposed between the core material and the noble metal-coating layer.

4. A noble metal-coated copper wire for ball bonding according to claim 3, wherein the noble metal-coating layer further comprises a gold ultra-thin stretched layer deposed on the palladium cavitating layer.

5. The noble metal-coated copper wire for ball bonding according to claim 1, wherein the at least one element is selected from the group consisting of sulfur, carbon, phosphorus, boron, silicon, germanium, arsenic, selenium, indium, tin, antimony, tellurium, bismuth, or oxide thereof.

6. The noble metal-coated copper wire for ball bonding according to claim 1, wherein the at least one element is selected from the group consisting of sulfur, phosphorus, selenium, tellurium, or oxygen element.

7. The noble metal-coated copper wire for ball bonding according to claim 1, wherein the at least one elements is sulfur.

8. The noble metal-coated copper wire for ball bonding according to claim 1, wherein the at least one element is carbon.

9. The noble metal-coated copper wire for ball bonding according to claim 1, wherein the noble metal-coating layer has a theoretical film thickness of 20 nm or more, and 300 nm or less.

10. The noble metal-coated copper wire for ball bonding according to claim 1, wherein the oxygen element is present on a surface of the noble metal-coating layer.

11. The noble metal-coated copper wire for ball bonding according to claim 1, wherein the copper is present on a surface of the noble metal-coating layer.

12. The noble metal-coated copper wire for ball bonding according to claim 1, wherein the core material is a copper alloy containing 0.003 mass % or more and 0.2 mass % or less of phosphorus.

13. The noble metal-coated copper wire for ball bonding according to claim 1, wherein the core material is a copper alloy containing at least one member selected from the group consisting of platinum, palladium, or nickel in a total amount of 0.1 mass % or more and 2 mass % or less.

14. The noble metal-coated copper wire for ball bonding according to claim 1, wherein the core material is a copper alloy containing 0.1 mass ppm or more and 10 mass ppm or less of hydrogen.

15. The noble metal-coated copper wire for ball bonding according to claim 1, wherein the palladium cavitating layer is a stretched wet plating layer.

16. The noble metal-coated copper wire for ball bonding according to claim 3, wherein the at least one element is selected from the group consisting of sulfur, carbon, phosphorus, boron, silicon, germanium, arsenic, selenium, indium, tin, antimony, tellurium, bismuth, or oxide thereof.

17. The noble metal-coated copper wire for ball bonding according to claim 3, wherein the core material is a copper alloy containing at least one member selected from the group consisting of platinum, palladium, or nickel in a total amount of 0.1 mass % or more and 2 mass % or less.
